(19) United States
(12) Patent Application Publication
(10) Pub. No.: US 2025/0258254 A1
(43) Pub. Date: Aug. 14, 2025

(54) CHIPLET SYSTEMS AND METHODS FOR QUANTUM SENSING

(71) Applicant: Toyota Motor Engineering & Manufacturing North America, Inc., Plano, TX (US)

(72) Inventors: Ercan Mehmet DEDE, Ann Arbor, MI (US); Paul Donald SCHMALENBERG, Ann Arbor, MI (US)

(73) Assignees: Toyota Motor Engineering & Manufacturing North America, Inc., Plano, TX (US); Toyota Jidosha Kabushiki Kaisha, Toyota-shi (JP)

(21) Appl. No.: 18/441,917

(22) Filed: Feb. 14, 2024

(51) Int. Cl. G01R 33/12

(52) U.S. Cl. CPC G01R 33/1284

(57) ABSTRACT

A quantum sensor chiplet system, and method and computer program product for creating a quantum sensor chiplet system. A substrate may be fabricated. A microwave antenna may be coupled to the substrate. An interposer may be coupled to the substrate. One or more quantum material chips may be coupled to the interposer. One or more processors may be coupled to the interposer. One or more storage devices may be coupled to the interposer.

### BACKGROUND

Quantum Sensing stands at the forefront of sensor technology, revolutionizing the precision with which we measure, navigate, study, explore, perceive, and engage with our surroundings by detecting changes in motion, electric fields, and magnetic fields. The change in measured physical state generally occurs at the atomic level, leveraging quantum resources—subtle phenomena observable only on an atomic scale—to achieve unparalleled accuracy.

### SUMMARY

In one example implementation, a method for creating a quantum sensor chiplet system may include but is not limited to fabricating a substrate. A microwave antenna may be coupled to the substrate. An interposer may be coupled to the substrate. One or more quantum material chips may be coupled to the interposer. One or more processors may be coupled to the interposer. One or more storage devices may be coupled to the interposer.

One or more of the following example features may be included. A light source may be coupled to at least one of the one or more quantum material chips and a photonic integrated circuit. One or more detectors may be coupled to at least one of the one or more quantum material chips and a photonic integrated circuit. A Voltage-Controlled Oscillator (VCO) and a Phase-Locked Loop (PLL) may be coupled to the microwave antenna designed to operate in the microwave frequency range. A heat sink layer may be coupled to a thermal gap pad. The thermal gap pad may be coupled to one of the substrate, at least one of the one or more quantum material chips, the light source, and at least one processor of the one or more processors. Nitrogen vacancy material may be coupled to at least one of the one or more quantum material chips.

In another example implementation, a quantum sensor chiplet system may include but is not limited to a substrate. The quantum sensor chiplet system may further include a microwave antenna coupled to the substrate. The quantum sensor chiplet system may further include an interposer coupled to the substrate. The quantum sensor chiplet system may further include one or more quantum material chips coupled to the interposer. The quantum sensor chiplet system may further include one or more processors coupled to the interposer. The quantum sensor chiplet system may further include one or more storage devices coupled to the interposer.

One or more of the following example features may be included. The quantum sensor chiplet system may further include a light source coupled to at least one of the one or more quantum material chips and a photonic integrated circuit. The quantum sensor chiplet system may further include one or more detectors coupled to at least one of the one or more quantum material chips and a photonic integrated circuit. The quantum sensor chiplet system may further include a Voltage-Controlled Oscillator (VCO) and a Phase-Locked Loop (PLL) coupled to the microwave antenna designed to operate in the microwave frequency range. The quantum sensor chiplet system may further include a heat sink layer coupled to a thermal gap pad. The thermal gap pad may be coupled to one of the substrate, at least one of the one or more quantum material chips, the light source, and at least one processor of the one or more processors. The quantum sensor chiplet system may further include nitrogen vacancy material coupled to at least one of the one or more quantum material chips.

In another example implementation, a computer program product may reside on a computer readable storage medium having a plurality of instructions stored thereon which, when executed across one or more processors, may cause at least a portion of the one or more processors to perform operations for creating a quantum sensor chiplet system may include but is not limited to fabricating a substrate. A microwave antenna may be coupled to the substrate. An interposer may be coupled to the substrate. One or more quantum material chips may be coupled to the interposer. One or more processors may be coupled to the interposer. One or more storage devices may be coupled to the interposer.

One or more of the following example features may be included. A light source may be coupled to at least one of the one or more quantum material chips and a photonic integrated circuit. One or more detectors may be coupled to at least one of the one or more quantum material chips and a photonic integrated circuit. A Voltage-Controlled Oscillator (VCO) and a Phase-Locked Loop (PLL) may be coupled to the microwave antenna designed to operate in the microwave frequency range. A heat sink layer may be coupled to a thermal gap pad. The thermal gap pad may be coupled to one of the substrate, at least one of the one or more quantum material chips, the light source, and at least one processor of the one or more processors. Nitrogen vacancy material may be coupled to at least one of the one or more quantum material chips.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF DRAWINGS

FIG. 1 is an example diagrammatic side view of a quantum sensor detection and data processing chiplet device according to one or more example implementations of the disclosure; and

FIG. 2 is an example flowchart of a fabrication process according to one or more example implementations of the disclosure.

Like reference symbols in the various drawings may indicate like elements.

### DESCRIPTION

### System Overview:

In some implementations, the present disclosure may be embodied as a method, system, or computer program product. Accordingly, in some implementations, the present disclosure may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, in some implementations, the present disclosure may take the form of a computer program product on a computer-usable storage medium having computer-usable program code embodied in the medium.

Software may include artificial intelligence systems, which may include machine learning or other computational intelligence. For example, artificial intelligence (AI) may include one or more models used for one or more problem domains. When presented with many data features, identification of a subset of features that are relevant to a problem domain may improve prediction accuracy, reduce storage space, and increase processing speed. This identification may be referred to as feature engineering. Feature engineering may be performed by users or may only be guided by users. In various implementations, a machine learning system may computationally identify relevant features, such as by performing singular value decomposition on the contributions of different features to outputs.

In some implementations, the various computing devices may include, integrate with, link to, exchange data with, be governed by, take inputs from, and/or provide outputs to one or more AI systems, which may include models, rule-based systems, expert systems, neural networks, deep learning systems, supervised learning systems, robotic process automation systems, natural language processing systems, intelligent agent systems, self-optimizing and self-organizing systems, and others. Except where context specifically indicates otherwise, references to AI, or to one or more examples of AI, should be understood to encompass one or more of these various alternative methods and systems; for example, without limitation, an AI system described for enabling any of a wide variety of functions, capabilities and solutions described herein (such as optimization, autonomous operation, prediction, control, orchestration, or the like) should be understood to be capable of implementation by operation on a model or rule set; by training on a training data set of human tag, labels, or the like; by training on a training data set of human interactions (e.g., human interactions with software interfaces or hardware systems); by training on a training data set of outcomes; by training on an AI-generated training data set (e.g., where a full training data set is generated by AI from a seed training data set); by supervised learning; by semi-supervised learning; by deep learning; or the like. For any given function or capability that is described herein, neural networks of various types may be used, including any of the types described herein, and in embodiments a hybrid set of neural networks may be selected such that within the set a neural network type that is more favorable for performing each element of a multi-function or multi-capability system or method is implemented. As one example among many, a deep learning, or black box, system may use a gated recurrent neural network for a function like language translation for an intelligent agent, where the underlying mechanisms of AI operation need not be understood as long as outcomes are favorably perceived by users, while a more transparent model or system and a simpler neural network may be used for a system for automated governance, where a greater understanding of how inputs are translated to outputs may be needed to comply with regulations or policies.

Examples of the models include recurrent neural networks (RNNs) such as long short-term memory (LSTM), deep learning models such as transformers, decision trees, support-vector machines, genetic algorithms, Bayesian networks, and regression analysis. Examples of systems based on a transformer model include bidirectional encoder representations from transformers (BERT) and generative pre-trained transformers (GPT). Training a machine-learning model may include supervised learning (for example, based on labelled input data), unsupervised learning, and reinforcement learning. In various embodiments, a machine-learning model may be pre-trained by their operator or by a third party. Problem domains include nearly any situation where structured data can be collected, and includes natural language processing (NLP), computer vision (CV), classification, image recognition, etc. Some or all of the software may run in a virtual environment rather than directly on hardware. The virtual environment may include a hypervisor, emulator, sandbox, container engine, etc. The software may be built as a virtual machine, a container, etc. Virtualized resources may be controlled using, for example, a DOCKER container platform, a pivotal cloud foundry (PCF) platform, etc. Some or all of the software may be logically partitioned into microservices. Each microservice offers a reduced subset of functionality. In various embodiments, each microservice may be scaled independently depending on load, either by devoting more resources to the microservice or by instantiating more instances of the microservice. In various embodiments, functionality offered by one or more microservices may be combined with each other and/or with other software not adhering to a microservices model.

In some implementations, any suitable computer usable or computer readable medium (or media) may be utilized. The computer readable medium may be a computer readable signal medium or a computer readable storage medium. The computer-usable, or computer-readable, storage medium (including a storage device associated with a computing device or client electronic device) may be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium or storage device may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, solid state drives (SSDs), a digital versatile disk (DVD), a Blu-ray disc, and an Ultra HD Blu-ray disc, a static random access memory (SRAM), dynamic RAM (DRAM), synchronous DRAM (SDRAM), synchronous graphics RAM (SGRAM), and video RAM (VRAM), analog magnetic tape, digital magnetic tape, rotating hard disk drive (HDDs), a memory stick, a floppy disk, a mechanically encoded device such as punch-cards or raised structures in a groove having instructions recorded thereon, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of the present disclosure, a computer-usable or computer-readable, storage medium may be any tangible medium that can contain or store a program for use by or in connection with the instruction execution system, apparatus, or device.

Examples of storage implemented by the storage hardware include a distributed ledger, such as a permissioned or permissionless blockchain. Entities recording transactions, such as in a blockchain, may reach consensus using an algorithm such as proof-of-stake, proof-of-work, and proof-of-storage. Elements of the present disclosure may be represented by or encoded as non-fungible tokens (NFTs). Ownership rights related to the non-fungible tokens may be recorded in or referenced by a distributed ledger. Transactions initiated by or relevant to the present disclosure may use one or both of fiat currency and cryptocurrencies, examples of which include bitcoin and ether.

In some implementations, a computer readable signal medium may include a propagated data signal with computer readable program code embodied therein, for example, in baseband or as part of a carrier wave. In some implementations, such a propagated signal may take any of a variety of forms, including, but not limited to, electromagnetic, optical, or any suitable combination thereof. In some implementations, the computer readable program code may be transmitted using any appropriate medium, including but not limited to the internet, wireline, optical fiber cable, RF, etc. In some implementations, a computer readable signal medium may be any computer readable medium that is not a computer readable storage medium and that can communicate, propagate, or transport a program for use by or in connection with an instruction execution system, apparatus, or device.

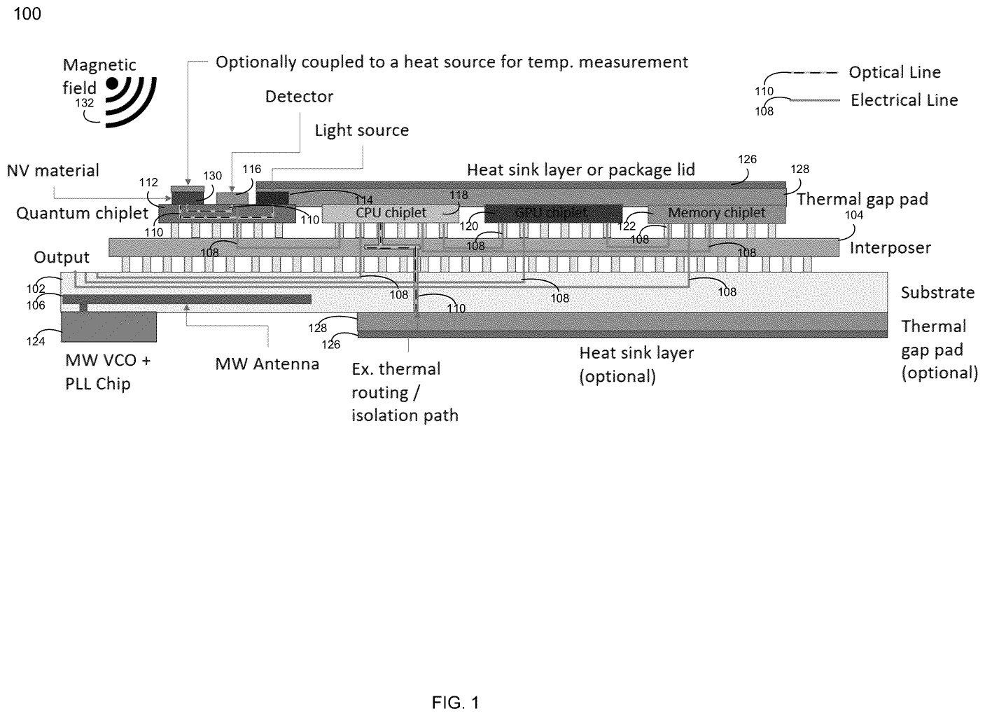

In some implementations, computer program code for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java®, Smalltalk, C++ or the like. Java® and all Java-based trademarks and logos are trademarks or registered trademarks of Oracle and/or its affiliates. However, the computer program code for carrying out operations of the present disclosure may also be written in conventional procedural programming languages, such as the “C” programming language, PASCAL, or similar programming languages, as well as in scripting languages such as JavaScript, PERL, or Python. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a network, such as a cellular network, local area network (LAN), a wide area network (WAN), a body area network BAN), a personal area network (PAN), a metropolitan area network (MAN), etc., or the connection may be made to an external computer (for example, through the internet using an Internet Service Provider). The networks may include one or more of point-to-point and mesh technologies. Data transmitted or received by the networking components may traverse the same or different networks. Networks may be connected to each other over a WAN or point-to-point leased lines using technologies such as Multiprotocol Label Switching (MPLS) and virtual private networks (VPNs), etc. In some implementations, electronic circuitry including, for example, programmable logic circuitry, an application specific integrated circuit (ASIC), gate arrays such as field-programmable gate arrays (FPGAs) or other hardware accelerators, micro-controller units (MCUs), or programmable logic arrays (PLAs), integrated circuits (ICs), digital circuit elements, analog circuit elements, combinational logic circuits, digital signal processors (DSPs), complex programmable logic devices (CPLDs), etc. may execute the computer readable program instructions/code by utilizing state information of the computer readable program instructions to personalize the electronic circuitry, in order to perform aspects of the present disclosure. Multiple components of the hardware may be integrated, such as on a single die, in a single package, or on a single printed circuit board or logic board. For example, multiple components of the hardware may be implemented as a system-on-chip. A component, or a set of integrated components, may be referred to as a chip, chipset, chiplet, or chip stack. Examples of a system-on-chip include a radio frequency (RF) system-on-chip, an artificial intelligence (AI) system-on-chip, a video processing system-on-chip, an organ-on-chip, a quantum algorithm system-on-chip, and as will be discussed in greater detail below, the device shown in FIG. 1., etc.

Examples of processing hardware may include, e.g., a central processing unit (CPU), a graphics processing unit (GPU), an approximate computing processor, a quantum computing processor, a parallel computing processor, a neural network processor, a signal processor, a digital processor, an analog processor, a data processor, an embedded processor, a microprocessor, and a co-processor. The co-processor may provide additional processing functions and/or optimizations, such as for speed or power consumption. Examples of a co-processor include a math co-processor, a graphics co-processor, a communication co-processor, a video co-processor, and an artificial intelligence (AI) co-processor.

In some implementations, the flowchart and block diagrams in the figures illustrate the architecture, functionality, and operation of possible implementations of apparatus (systems), methods and computer program products according to various implementations of the present disclosure. Each block in the flowchart and/or block diagrams, and combinations of blocks in the flowchart and/or block diagrams, may represent a module, segment, or portion of code, which comprises one or more executable computer program instructions for implementing the specified logical function(s)/act(s). These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of the order noted in the figures (or combined or omitted). For example, two blocks shown in succession may, in fact, be executed substantially concurrently, or the blocks may sometimes be executed in the reverse order, depending upon the functionality involved.

In some implementations, these computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

In some implementations, the instruction sets and subroutines of fabrication process 200, which may be stored on storage device, coupled to a computer, may be executed by one or more processors and one or more memory architectures included within the computer. In some implementations, the storage device may include any of the storage device/memory devices described throughout. It will be appreciated after reading the present disclosure that the terms storage device and memory may be used interchangeably depending on the context. It will be appreciated after reading the present disclosure that any portion of fabrication process 200 may be used in a manufacturing process that is manufactured from separate chips that are combined (assembled) in a manufacturing facility or similar.

In some implementations, a network may be connected to one or more secondary networks, examples of which may include but are not limited to: a local area network; a wide area network or other telecommunications network facility; or an intranet, for example. The phrase “telecommunications network facility,” as used herein, may refer to a facility configured to transmit, and/or receive transmissions to/from one or more mobile client electronic devices (e.g., cellphones, etc.) as well as many others.

Examples of client electronic devices or computers that may be used with device 100 may include, but are not limited to, a personal computer, a laptop computer, a smart/data-enabled, cellular phone, a notebook computer, a tablet, a server, a television, a smart television, a smart speaker, an Internet of Things (IoT) device, a media (e.g., audio/video, photo, etc.) capturing and/or output device, an audio input and/or recording device (e.g., a handheld microphone, a lapel microphone, an embedded microphone/speaker (such as those embedded within eyeglasses, smart phones, tablet computers, smart televisions, smart speakers, watches, etc.), a dedicated network device, and combinations thereof. The client electronic devices may each execute an operating system, examples of which may include but are not limited to, Android™, Apple® iOS®, Mac® OS X®; Red Hat® Linux®, Windows® Mobile, Chrome OS, Blackberry OS, Fire OS, or a custom operating system.

In some implementations, the various client electronic devices, along with device 100, may be directly or indirectly coupled to a network. For example, device 100 may be hardwired to the network or wirelessly coupled to the network via wireless communication channel established between device 100 and a wireless access point (WAP). The WAP may be, for example, an IEEE 802.11a, 802.11b, 802.11g, 802.11n, 802.11ac, Wi-Fi®, RFID, and/or Bluetooth™ (including Bluetooth™ Low Energy) or any device that is capable of establishing a wireless communication channel between device 100 and the WAP. Device 100 may be wirelessly coupled to a network via a wireless communication channel established between a client electronic device and a cellular network/bridge, which may be directly coupled to the network.

In some implementations, some or all of the IEEE 802.11x specifications may use Ethernet protocol and carrier sense multiple access with collision avoidance (i.e., CSMA/CA) for path sharing. The various 802.11x specifications may use phase-shift keying (i.e., PSK) modulation or complementary code keying (i.e., CCK) modulation, for example. Bluetooth™ (including Bluetooth™ Low Energy) is a telecommunications industry specification that allows, e.g., mobile phones, computers, smart phones, and other electronic devices to be interconnected using a short-range wireless connection. Other forms of interconnection (e.g., Near Field Communication (NFC)) may also be used. In some implementations, device 100 may be directed or controlled by an operator. Device 100 may be hosted by one or more of assets owned by the operator, assets leased by the operator, and third-party assets. The assets may be referred to as a private, community, or hybrid cloud computing network or cloud computing environment. For example, device 100 may be partially or fully hosted by a third party offering software as a service (Saas), platform as a service (PaaS), and/or infrastructure as a service (IaaS). Device 100 may be implemented using agile development and operations (DevOps) principles. In some implementations, some or all of device 100 may be implemented in a multiple-environment architecture. For example, the multiple environments may include one or more production environments, one or more integration environments, one or more development environments, etc.

Quantum Sensing stands at the forefront of sensor technology, revolutionizing the precision with which we measure, navigate, study, explore, perceive, and engage with our surroundings by detecting changes in motion, electric fields, and magnetic fields. The change in measured physical state generally occurs at the atomic level, leveraging quantum resources—subtle phenomena observable only on an atomic scale—to achieve unparalleled accuracy.

The operational principles of Quantum Sensing generally involve gathering “delicate” data at the atomic level, often extracting information from individual atoms rather than relying on large collections, as seen in classical physics. This approach has the potential to exponentially enhance the accuracy, thoroughness, efficiency, and productivity of technological devices utilizing quantum sensors.

Quantum sensing excels in collecting precise data by harnessing atomic properties, allowing for advancements in existing technologies. Examples of its applications in daily life may include magnetic field sensing, e.g., Enhanced Geolocation: Faster, more accurate, and reliable than current satellite-dependent GPS devices, with fewer limitations; Medical Imaging: Providing doctors with more detailed and cost-effective biological diagnostic images or data with fewer potential side effects for patients; Autonomous Navigation: Safer navigation for vehicles on land, in the air, and at sea, even in high-traffic areas and around unexpected obstacles; Space and Underwater Systems: More accurate and less vulnerable guidance systems in space, underwater, and in areas saturated with radio-frequency signals; Underground Exploration: Reliable detection, imaging, and mapping of underground environments, from transit tunnels to ancient ruins; Extracting Data at the Atomic Level.

Quantum sensors utilize “quantum resources” to measure atomic changes with greater precision than traditional methods. These resources include entanglement, quantum interference (superposition), discrete states, spin, and coherence. Quantum optics, which often relies on light or photons, can be extended to other mediums such as atoms in free space and certain solid-state devices.

As quantum sensing transitions from a niche capability to widespread adoption, it is expected to significantly enhance capabilities across various industries, including, e.g., Aircraft and Automobile Manufacturing; Border and Immigration Controls; Climatology and Weather Forecasting; Computer and Electronics Development; Cyber Security; Defense and Intelligence Systems; Emergency and Disaster Recovery Services; Environmental Management; Geology and Civil Engineering; Government Agencies; Health Care and Medicine; Biological Monitoring; Insurance; Law Enforcement; Minerals and Mining; State and Municipal Services; Shipping; Space Exploration; Transit Companies; Universities; Utilities and Power Grid Services, etc.

Despite its promising potential, realizing the benefits of Quantum Sensing requires robust development environments that support aggressive innovation. Therefore, as will be discussed in greater detail below, the present disclosure describes a full quantum sensor detection and data processing device (e.g., device 100) in which a printed circuit board (PCB) substrate hosts a microwave antenna and multiple quantum material chips, processors, and memory storage devices are mounted on an interposer.

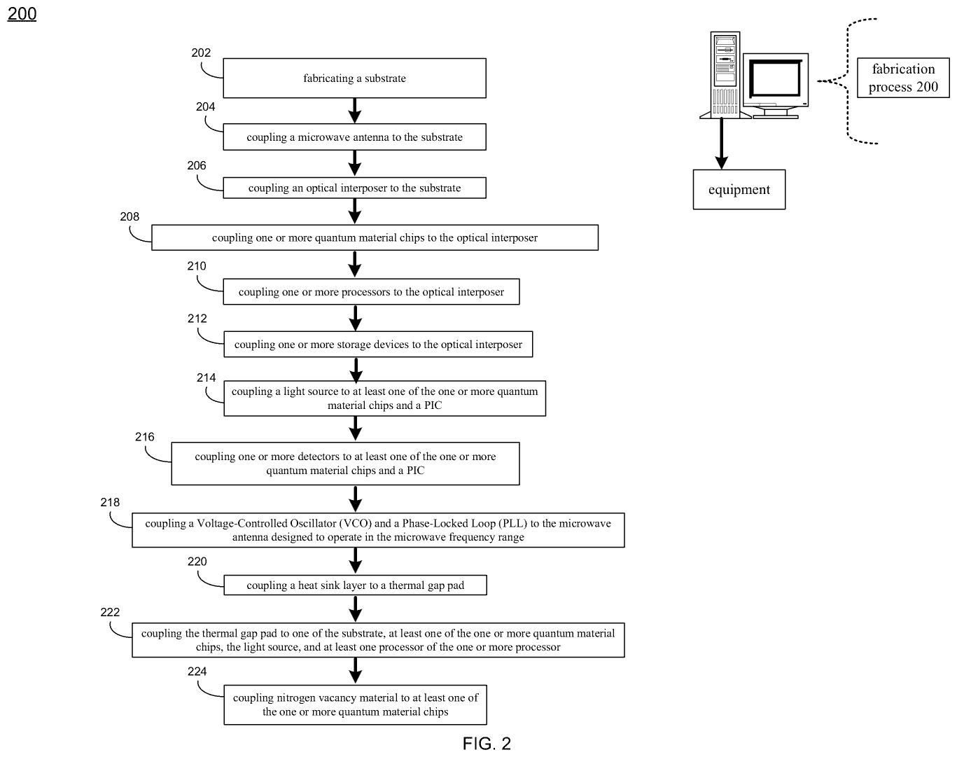

As discussed above and referring also at least to the example implementations of FIGS. 1-2, a quantum sensor chiplet system may include but is not limited to a substrate. The quantum sensor chiplet system may further include a microwave antenna coupled to the substrate. The quantum sensor chiplet system may further include an interposer coupled to the substrate. The quantum sensor chiplet system may further include one or more quantum material chips coupled to the interposer. The quantum sensor chiplet system may further include one or more processors coupled to the interposer. The quantum sensor chiplet system may further include one or more storage devices coupled to the interposer.

In some implementations, a quantum sensor chiplet system may include quantum material “chips” with one or more parts that are assembled with traditional integrated circuit chips and memory chips for a full quantum sensor detection and data processing device. Generally, a quantum material chip refers to a substrate, semiconductor chip, or device that incorporates materials exhibiting quantum properties, often for the purpose of harnessing quantum effects for information processing or sensing applications. These chips play a crucial role in the field of quantum information science and technology, which aims to leverage the principles of quantum mechanics for various computational and sensing tasks. Generally, the term “quantum material” refers to a class of materials that exhibit unique quantum phenomena, such as spin, superposition, and/or entanglement, which are fundamental to quantum mechanics. Quantum material chips are designed to manipulate and control these quantum properties at the microscopic level, allowing for the creation of quantum states. Some example key aspects of a quantum material chip:

Quantum Sensors: In addition to quantum computation, quantum material chips may be designed for quantum sensing applications. Quantum sensors exploit quantum properties (such as spin states) for highly sensitive measurements, such as magnetic field (e.g., magnetic field 132) sensing, gravitational field sensing, or precision measurements of physical quantities.

Materials with Unique Quantum Properties: The choice of materials for a quantum material chip is critical. Superconducting materials, semiconductor-based quantum dots, and topological insulators are examples of materials that have been explored for their unique quantum properties. In some implementations, for sensing in particular, the present disclosure may use color center materials, such as diamond or hBN. They may be mounted on substrates, such as sapphire.

Cryogenic Conditions: Many quantum material chips operate at extremely low temperatures, often close to absolute zero, to maintain the coherence of particular quantum states. Cryogenic conditions help reduce decoherence, allowing for more stable and reliable quantum operations. It will be appreciated that the present disclosure may be used in room temperature operation as well, hence the use of diamond (e.g., a bulk substrate or nanodiamonds) or hBN.

Control and Measurement Electronics: Quantum material chips are typically accompanied by control and measurement electronics. These components enable the manipulation and readout of spin states and provide the necessary interfaces for external control and communication.

Integration with Classical Computing Components: Quantum material chips are often part of hybrid systems that include classical computing components for tasks such as error correction, control, and interfacing with the broader computing infrastructure.

Research and Development: Quantum material chips are a focal point of ongoing research and development in the field of quantum information science. Researchers continually explore new materials, fabrication techniques, and architectures to improve the performance, coherence time, and scalability of quantum material chips.

Examples of quantum material platforms may include spin states obtained with color center materials, although other platforms may also be used without departing from the scope of the present disclosure.

For instance, in some implementations, a quantum sensor chiplet system (e.g., such as device 100) may include a substrate (e.g., substrate 102), and in some implementations, the quantum sensor chiplet system may further include an interposer (e.g., interposer 104) coupled to substrate 102. In some implementations, interposer 104 may be an electrical interposer, an optical interposer, organic interposer, silicon interposer, Embedded Multi-die Interconnect Bridge (EMIB), other substrate, etc. For simplicity, the present disclosure is described as an electrical interposer. In the following example, substrate 102 is described as a Printed Circuit Board (PCB) substrate; however, it will be appreciated by one skilled in the art after reading the present disclosure that other types of substrates (e.g., Rogers Laminates, PTFE-based materials, ceramic, glass-reinforced epoxy, liquid crystal polymer, flexible substrates, ceramic-polymer composites, quartz, etc.) may also be used without departing from the scope of the present disclosure. In the example, substrate 102 may host a microwave antenna (e.g., microwave antenna 106) and may serve as the substrate on which an interposer 104 is positioned. In some implementations, interposer 104 may be fabricated of a suitable material for light-based communications with embedded electrical function (via electrical line 108) and optical line or optical waveguide 110. Interposer 104 may then serve as the foundation for mounting multiple quantum material (QM) chips (e.g., photonic integrated circuit (PIC) 112, which may have optical waveguides), a light source (Gain) (e.g., light source 114), detectors (e.g., detector 116), processors (Logic, or Signal Processors such as CPU chiplet 118, GPU chiplet 120), and memory storage devices (e.g., memory 122). In some implementations, PIC 112 may be a photonic integrated circuit (PIC) comprising an optical substrate (e.g., SiN) with waveguides fabricated into it to carry light from light source 114 to the quantum “nitrogen vacancy” (NV material 130) and from the quantum material to detector 116. Interposer 104 may then allow for light-based communication in addition to electrical signal processing between the various chips for quantum sensing, recovering of the sensed signal, digital processing of the signal via an integrated software algorithm to convert it into a usable sensing value, and memory to store recovered sensing and processing data real-time.

As noted above, in some implementations, the quantum sensor chiplet system may further include microwave antenna 106 coupled to substrate 102. For example, coupling microwave antenna 106 to substrate 102 may be accomplished using techniques such as, e.g., a feed line, a coaxial cable connection, a microstrip patch antenna, a coplanar waveguide, etc.

As noted above, in some implementations, the quantum sensor chiplet system may further include one or more quantum material chips coupled to an optical interposer. For example, as can be seen from FIG. 1, quantum material chip (e.g., PIC 112) is coupled to interposer 104. The quantum chiplet may be (or include) a PIC as mentioned above, and may pass information (e.g., digital electrical) from the detector to the electrical interposer. So, the PIC can be bump bonded to the interposer in a standard fashion. Thus, unlike prior systems, the present disclosure includes a PIC in combination with other chiplets that form a quantum sensor chiplet system that may be configured on the interposer in combination with the MW source modularly depending on the sensing application.

As noted above, in some implementations, the quantum sensor chiplet system may further include one or more processors coupled to the optical interposer. For example, as can be seen from FIG. 1, processors (e.g., CPU chiplet 118) is shown coupled to interposer 104.

As noted above, in some implementations, the quantum sensor chiplet system may further include one or more storage devices coupled to the optical interposer. For example, as can be seen from FIG. 1, one or more storage devices (e.g., memory chiplet 122) is shown being coupled to interposer 104.

As noted above, in some implementations, the quantum sensor chiplet system may further include a light source coupled to at least one of the one or more quantum material chips and a photonic integrated circuit. For example, as can be seen from FIG. 1, a light source (e.g., light source 114) is shown coupled to quantum material chiplet (e.g., PIC 112).

As noted above, in some implementations, the quantum sensor chiplet system may further include one or more detectors coupled to at least one of the one or more quantum material chips. For example, as can be seen from FIG. 1, one or more detectors (e.g., detector 116) is shown coupled to PIC 112. Example detectors that may be used include, e.g., Superconducting Transition Edge Sensors (TES), semiconductor quantum dot detectors, Single-Photon Avalanche Diodes (SPAD), Photomultiplier Tubes (PMT), Single-Electron Transistors (SET), Ion Detectors (for Ion Trap Qubits), Optical Detectors (e.g., Avalanche Photodiodes), etc. The NV material may be positioned mechanically (in the case of bulk silicon) using epoxy, for example, or deposited as a nanodiamond powder, which is suspended in solution and then evaporated onto the substrate, perhaps encased in PDMS, or tape transferred or CVD grown in the case of hBN.

In some implementations, the quantum sensor chiplet system may further include a Voltage-Controlled Oscillator (VCO) and a Phase-Locked Loop (PLL) coupled to the microwave antenna designed to operate in the microwave frequency range. For example, as can be seen from FIG. 1, a VCO/PLL (e.g., VCO/PLL 124) may be coupled to microwave antenna 106 and act on NV material 130 . . . . Generally, a microwave VCO+PLL chip refers to a chip that integrates a Voltage-Controlled Oscillator (VCO) and a Phase-Locked Loop (PLL) designed to operate in the microwave frequency range. A VCO is generally an electronic oscillator with an output frequency that can be adjusted (tuned) by varying the voltage applied to its input. In the context of a microwave VCO, it means the VCO is designed to operate in the microwave frequency range, typically covering frequencies above 1 GHz. A PLL is generally a closed-loop feedback control system that automatically adjusts the phase of an output signal to match the phase of a reference signal. In the case of a microwave VCO+PLL chip, the PLL component may be used to stabilize and control the output frequency of the VCO, ensuring it stays within a specified range and aligns with a reference frequency. Combining the VCO and PLL functionalities into a single chip can offer advantages such as compactness, improved performance, and simplified integration into electronic systems. This kind of chip may be used in many applications, including, e.g., communication systems, radar systems, and other applications where precise frequency control in the microwave range is crucial. The specific application of VCO/PLL 124 chip can vary, and it might be used in, e.g., wireless communication devices, microwave transceivers, frequency synthesizers, or other systems where stable and tunable microwave frequencies are required.

In some implementations, the quantum sensor chiplet system may further include a heat sink layer coupled to a thermal gap pad, and in some implementations, the thermal gap pad may be coupled to one of the substrate, at least one of the one or more quantum material chips, the light source, and at least one processor of the one or more processors. For example, as can be seen from FIG. 1, a heat sink layer (e.g., heat sink layer 126 or package lid) is shown coupled to a thermal gap pad (e.g., thermal gap pad 128), and thermal gap pad 128 is shown coupled to substrate 102, at least one of the quantum material chips, light source 114, CPU chiplet 118, GPU chiplet 120, and memory 122. For thermal management of the chiplet package, an overlaying and conformal thermal interface material (TIM) may be positioned over the top side of the package on to which a heat sink is ultimately attached.

In some implementations, the quantum sensor chiplet system may further include nitrogen vacancy material coupled to at least one of the one or more quantum material chips. For example, as can be seen from FIG. 1, a Nitrogen-Vacancy (NV) material (e.g., NV material 130) is shown coupled to PIC 112. In some implementations, NV material 130 may be coupled to a heat source for temperature measurement.

FIG. 2 is a flowchart of an example method for creating a quantum sensor chiplet system using, for example, a foundry, chip fabrication facility, etc. As noted above, it will be appreciated after reading the present disclosure that any portion of fabrication process 200 may be used in a manufacturing process that is manufactured from separate chips that are combined (assembled) in a manufacturing facility (e.g., foundry, chip fabrication facility or similar). As such, as discussed above and referring also at least to the example implementations of FIGS. 1-2, fabrication process 200 may fabricate 202 fabricating a substrate. In some implementations, fabrication process 200 may couple 204 a microwave antenna to the substrate. In some implementations, fabrication process 200 may couple 206 an interposer to the substrate. In some implementations, fabrication process 200 may couple 208 one or more quantum material chips to the interposer. In some implementations, fabrication process 200 may couple 210 one or more processors to the interposer. In some implementations, fabrication process 200 may couple 212 one or more storage devices to the interposer.

In some implementations, fabrication process 200 may couple 214 a light source to at least one of the one or more quantum material chips (e.g., referred to herein for example purposes only as PIC 112). In some implementations, fabrication process 200 may couple 216 one or more detectors to at least one of the one or more quantum material chips. In some implementations, fabrication process 200 may couple 218 a Voltage-Controlled Oscillator (VCO) and a Phase-Locked Loop (PLL) to the microwave antenna designed to operate in the microwave frequency range. In some implementations, fabrication process 200 may couple 220 a heat sink layer to a thermal gap pad. In some implementations, fabrication process 200 may couple 222 the thermal gap pad to one of the substrate, at least one of the one or more quantum material chips, the light source, and at least one processor of the one or more processors. In some implementations, fabrication process 200 may couple 224 nitrogen vacancy material to at least one of the one or more quantum material chips.

It will be appreciated after reading the present disclosure that any standard PCB assembly/printing/fabrication, etc. equipment, as well as any other necessary equipment, and any particular location, such as at a foundry, chip fabrication facility, or any other facility with a system capable of heterogeneous integration, may be used singly or in any combination with fabrication process 200, which may be operatively connected to a computing device, such as the computing device shown in FIG. 2, to obtain their instructions for creating and/or executing one or more aspects of the present disclosure. In one or more example implementations, the respective flowcharts may be manually-implemented, computer-implemented, or a combination thereof.

The terminology used herein is for the purpose of describing particular implementations only and is not intended to be limiting of the disclosure. As used herein, the singular forms “a”, “an” and “the” are intended to include the plural forms as well, including any steps performed by a/the computer/processor, unless the context clearly indicates otherwise. As used herein, the phrase “at least one of A, B, and C” should be construed to mean a logical (A OR B OR C), using a non-exclusive logical OR, and should not be construed to mean “at least one of A, at least one of B, and at least one of C.” As another example, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof. Example sizes/models/values/ranges can have been given, although examples are not limited to the same.

The terms (and those similar to) “coupled,” “attached,” “connected,” “adjoining,” “transmitting,” “receiving,” “connected,” “engaged,” “adjacent,” “next to,” “on top of,” “above,” “below,” “abutting,” and “disposed,” used herein is to refer to any type of relationship, direct or indirect, between the components in question, and is to apply to electrical, mechanical, fluid, optical, electromagnetic, electromechanical, or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner. The term “set” does not necessarily exclude the empty set—in other words, in some circumstances a “set” may have zero elements. The term “non-empty set” may be used to indicate exclusion of the empty set—that is, a non-empty set must have one or more elements, but this term need not be specifically used. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

The corresponding structures, materials, acts, and equivalents (e.g., of all means or step plus function elements) that may be in the claims below are intended to include any structure, material, or act for performing the function in combination with other claimed elements as specifically claimed. While the disclosure describes structures corresponding to claimed elements, those elements do not necessarily invoke a means plus function interpretation unless they explicitly use the signifier “means for.” Unless otherwise indicated, recitations of ranges of values are merely intended to serve as a shorthand way of referring individually to each separate value falling within the range, and each separate value is hereby incorporated into the specification as if it were individually recited. While the drawings divide elements of the disclosure into different functional blocks or action blocks, these divisions are for illustration only. According to the principles of the present disclosure, functionality can be combined in other ways such that some or all functionality from multiple separately-depicted blocks can be implemented in a single functional block; similarly, functionality depicted in a single block may be separated into multiple blocks. Unless explicitly stated as mutually exclusive, features depicted in different drawings can be combined consistent with the principles of the present disclosure.

The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim may be combined with the features of any of the independent claims or other dependent claims.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A quantum sensor chiplet system comprising:
a substrate;
a microwave antenna coupled to the substrate;
an interposer coupled to the substrate;
one or more quantum material chips coupled to the interposer;
one or more processors coupled to the interposer; and
one or more storage devices coupled to the interposer.

2. The quantum sensor chiplet system of claim 1 further comprising a light source coupled to at least one of the one or more quantum material chips and a photonic integrated circuit.

3. The quantum sensor chiplet system of claim 1 further comprising one or more detectors coupled to at least one of the one or more quantum material chips and a photonic integrated circuit.

4. The quantum sensor chiplet system of claim 1 further comprising a Voltage-Controlled Oscillator (VCO) and a Phase-Locked Loop (PLL) coupled to the microwave antenna designed to operate in a microwave frequency range.

5. The quantum sensor chiplet system of claim 1 further comprising a heat sink layer coupled to a thermal gap pad.

6. The quantum sensor chiplet system of claim 5, wherein the thermal gap pad is coupled to one of the substrate, at least one of the one or more quantum material chips, a light source, and at least one processor of the one or more processors.

7. The quantum sensor chiplet system of claim 1 further comprising nitrogen vacancy material coupled to at least one of the one or more quantum material chips.

8. A computer program product residing on a computer readable storage medium having a plurality of instructions stored thereon which, when executed across one or more processors, causes at least a portion of the one or more processors to perform operations for creating a quantum sensor chiplet system comprising:
fabricating a substrate;
coupling a microwave antenna to the substrate;
coupling an interposer to the substrate;
coupling one or more quantum material chips to the interposer;
coupling one or more processors to the interposer; and
coupling one or more storage devices to the interposer.

9. The computer program product of claim 8, wherein the instructions further comprise coupling a light source to at least one of the one or more quantum material chips and a photonic integrated circuit.

10. The computer program product of claim 8, wherein the instructions further comprise coupling one or more detectors to at least one of the one or more quantum material chips and a photonic integrated circuit.

11. The computer program product of claim 8, wherein the instructions further comprise coupling a Voltage-Controlled Oscillator (VCO) and a Phase-Locked Loop (PLL) to the microwave antenna designed to operate in a microwave frequency range.

12. The computer program product of claim 8, wherein the instructions further comprise coupling a heat sink layer to a thermal gap pad.

13. The computer program product of claim 12, wherein the instructions further comprise coupling the thermal gap pad to one of the substrate, at least one of the one or more quantum material chips, a light source, and at least one processor of the one or more processors.

14. The computer program product of claim 8, wherein the instructions further comprise coupling nitrogen vacancy material to at least one of the one or more quantum material chips.

15. A method for creating a quantum sensor chiplet system comprising:
fabricating a substrate;
coupling a microwave antenna to the substrate;
coupling an interposer to the substrate;
coupling one or more quantum material chips to the interposer;
coupling one or more processors to the interposer; and
coupling one or more storage devices to the interposer.

16. The method of claim 15 further comprising coupling a light source to at least one of the one or more quantum material chips and a photonic integrated circuit.

17. The method of claim 15 further comprising coupling one or more detectors to at least one of the one or more quantum material chips and a photonic integrated circuit.

18. The method of claim 15 further comprising coupling a Voltage-Controlled Oscillator (VCO) and a Phase-Locked Loop (PLL) to the microwave antenna designed to operate in a microwave frequency range.

19. The method of claim 15 further comprising coupling a heat sink layer to a thermal gap pad, wherein the thermal gap pad is coupled to one of the substrate, at least one of the one or more quantum material chips, a light source, and at least one processor of the one or more processors.

20. The method of claim 15 further comprising coupling nitrogen vacancy material to at least one of the one or more quantum material chips.
